(19) United States
(12) Patent Application Publication
(10) Pub. No.: US 2003/0168094 A1
(43) Pub. Date: Sep. 11, 2003

(54) Thermoelectric material and process for manufacturing the same

(75) Inventors: Norihiko Miyasita, Ageo (JP); Tomoyasu Yano, Ageo (JP); Ryoma Tsukuda, Ageo (JP); Isamu Yashima, Ageo (JP)

Correspondence Address: SUGHRUE MION, PLLC, 2100 Pennsylvania Avenue, NW, Washington, DC, 20037-3213, US

(73) Assignee: MITSUI MINING & SMELTING CO., LTD.

(21) Appl. No.: 10/365,447

(22) Filed: Feb. 13, 2003

(30) Foreign Application Priority Data
Feb. 14, 2002 (JP) 2002-37250

(51) Int. Cl. H01L 35/20; B22F 1/00

(52) U.S. Cl. 136/240; 419/48

(57) ABSTRACT

A thermoelectric material is prepare by mixing and melting at least two members selected from bismuth, tellurium, selenium, antimony, and sulfur to obtain an alloy ingot; grinding the alloy ingot to obtain powder of the alloy ingot; and hot pressing the powder of the alloy ingot. The hot pressing is performed under the conditions of a temperature of 500° C. or higher and 600° C. or lower and a pressure of 20 MPa or higher and 45 MPa or lower.

### BACKGROUND OF THE INVENTION

1) Field of the Invention

The present invention relates to a thermoelectric material that is used as a material for thermoelectric devices utilizing Peltier effect or Seebeck effect and a process for preparing a thermoelectric material.

2) Description of the Related Art

A thermoelectric device utilizing Peltier effect and Seebeck effect can be used in a variety of utilities such as elements for heating and cooling and for temperature control, thermoelectric electricity generators and the like.

The thermoelectric device is made from a thermoelectric material. Performance properties of the thermoelectric material is evaluated by the thermoelectric figure of merit Z that is obtained through the following equation,

Z=α²/(ρ·κ) (1)

in which Z[1/K] is figure of merit, α[μV/K] is Seebeck coefficient, κ[mW/cm·K] is thermal conductivity, and ρ[mΩ·cm] is specific resistance.

If the figure of merit Z is higher, it means that the thermoelectric material has higher performance. To increase the figure of merit Z of the thermoelectric material, the Seebeck coefficient may be increased and/or the specific resistance ρ and the thermal conductivity κ may be decreased.

Meanwhile, p-type and n-type thermoelectric materials obtained by adding a suitable dopant to an alloy generally represented by (Bi, Sb)₂ (Te, Se, S)₃ containing at least two elements selected from the group consisting of bismuth (Bi), tellurium (Te), selenium (Se), antimony (Sb), and sulfur (S) are known to have higher figure of merit. However, since this thermoelectric material is a hexagonal crystal system, the physical properties thereof have the isotropy, and a figure of merit in a direction perpendicular to the c axis has a higher value than that of a figure of merit in a direction parallel with the c axis. The reason is as follows: The thermal conductivity in a direction perpendicular to the c axis is greater than that in a direction parallel with the c axis. However, since a power factor represented by α²/ρ is also greater in a direction perpendicular to the c axis than in a direction parallel with the c axis, a value of a figure of merit in a direction perpendicular to the c axis is consequently shows greater value. Therefore, when this thermoelectric material is used in a thermoelectric device, it is desirable that the element is designed so as to electrify in a direction perpendicular to the c axis. That is, by manufacturing this thermoelectric material as a single crystal shown in FIG. 7, or as a polycrystalline sample having c plane orientation shown in FIG. 8, it becomes possible to electrify in a direction perpendicular to the c axis.

In the case of a single crystal, as shown in FIG. 7, the resulting sample is composed of one crystal, and there is no grain boundary and, therefore, it is possible to realize the properties possessed by a crystal as they are. How a better single crystal can be produced leads to improvement in a figure of merit. In addition, in the case of a pillar single crystal shown in FIG. 7, a longitudinal direction of a single crystal is in the “a” axial direction, and the crystal is cleaved in this direction. Such single crystal is prepared by a method of weighing a raw material powder of Bi, Te, Se, Sb or S, and a dopant at prescribed amounts, sealing them in a quartz tube or a Pyrex (registered trademark) glass tube, the atmosphere of which has been replaced with hydrogen or argon gas, maintaining this sealed tube at a temperature higher than a melting point by 50° C. in a rocking furnace, to stir the melt well, and solidifying it in one direction in a Bridgeman Stockburger furnace.

In addition, in the case of a polycrystalline material having c plane orientation, as shown in FIG. 8, most of scaly crystal particles constituting a polycrystalline material are in the state where those particles are sintered with c axial directions arrayed. This polycrystalline material having c plane orientation is prepared by weighing Bi, Te, Se, Sb or S powder and a dopant at prescribed amounts, melting them into a polycrystalline material and, thereafter, finely-dividing the polycrystalline material to form powder of a thermoelectric raw material, extrusion-forming the powder of the thermoelectric raw material to form a green body, and heating and sintering the green body.

However, there is a problem that a single crystal or a polycrystalline material having c axis orientation of a thermoelectric material containing at least two elements selected from Bi, Te, Se, Sb and S has a low mechanical strength because cleavage is easily produced along the c plane. When the mechanical strength is low like this, crack and chipping are produced in obtaining a thermoelectric device by processing such as cutting, and material loss is increased, being responsible for the increase in cost.

On the other hand, a thermoelectric device using a thermoelectric material of a single crystal is easily destructed by a thermal stress produced upon its use, being responsible for reduced long term reliance.

### SUMMARY OF THE INVENTION

It is an object of the present invention to at least solve the problems in the conventional technology.

The thermoelectric material according to one aspect of the present invention is prepare by mixing and melting at least two members selected from bismuth, tellurium, selenium, antimony, and sulfur to obtain an alloy ingot; grinding the alloy ingot to obtain powder of the alloy ingot; and hot pressing the powder of the alloy ingot. The hot pressing is performed under the conditions of a temperature of 500° C. or higher and 600° C. or lower and a pressure of 20 MPa or higher and 45 MPa or lower.

The thermoelectric material prepared by the process according to the above aspect is characterized in that an orientation degree of a (001) plane of the thermoelectric material obtained by an X-ray diffraction method in a plane perpendicular to a hot press direction of the thermoelectric material is 0.2 or smaller.

The Peltier element according to another aspect of the present invention comprises an arrangement in which a plurality of p-type thermoelectric devices and n-type thermoelectric devices prepared by the process according to the above aspect are arranged alternately; electrodes that electrically connect adjoining p-type thermoelectric device and n-type thermoelectric device; and electrically insulating substrates that hold the electrodes.

These and other objects, features and advantages of the present invention are specifically set forth in or will become apparent from the following detailed descriptions of the invention when read in conjunction with the accompanying drawings.

### BRIEF DESCRIPTION OF THE DRAWINGS

FIG. 1 is a flow chart that shows a step of manufacturing a thermoelectric material of the present invention;

FIG. 2 is a graph that shows the relationship between the temperature and pressure conditions at hot pressing and a figure of merit of the produced thermoelectric material;

FIG. 3 is a schematic view that shows a structure of a Peltier element;

FIG. 4 is a schematic view that shows an optical module using the Peltier element;

FIG. 5 is a graph that shows the relationship between the c plane orientation degree and thermal conductivity in a p-type thermoelectric material (Sb_{0.8}Bi_{0.2})₂Te₃;

FIG. 6 is a graph that shows the relationship between the c plane orientation degree and a figure of merit in a p-type thermoelectric material (Sb_{0.8}Bi_{0.2})₂Te₃;

FIG. 7 is a schematic representation of a form of a thermoelectric material of a single crystal prepared by the previous process; and

FIG. 8 is a schematic representation of a form of a thermoelectric material of a c-plane oriented polycrystalline material prepared by the previous process.

### DETAILED DESCRIPTION

An exemplary embodiment of a process for manufacturing a p-type thermoelectric material of the present invention will be explained in detail below.

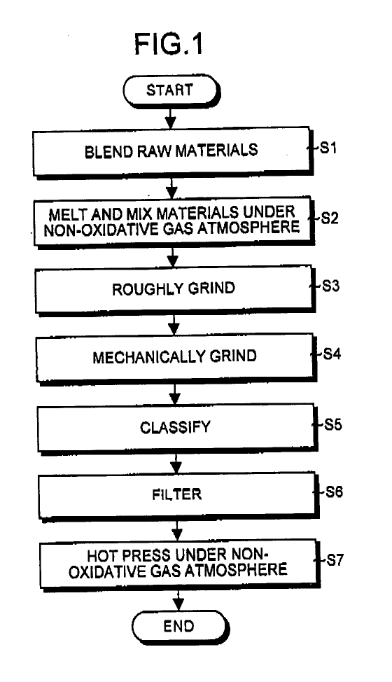

FIG. 1 is a flow chart of the process for manufacturing a thermoelectric material. First, elements constituting a desired thermoelectric material and, if necessary, a dopant are weighed at prescribed amounts and blended (step S1). In the present invention, as elements constituting a thermoelectric material, at least two elements selected from the group consisting of bismuth (Bi), tellurium (Te), selenium (Se), antimony (Sb) and sulfur (S) are used. In addition, a dopant is added as necessary in order to control and stabilize the carrier density of a thermoelectric material. In the case of a p-type thermoelectric material, Se and Te are used as the dopant. In the case of an n-type thermoelectric material, at least one selected from the group of bismuth fluoride (BiF₃), bismuth chloride (BiCl3), bismuth bromide (BiBr₃), bismuth iodide (BiI1), tellurium chloride (TeCl₄), tellurium iodide (TeI₂, TeI₄), tellurium bromide(TeBr₄), selenium chloride (SeCl₄), selenium bromide (SeBr₄), selenium iodide (SeI₄), antimony fluoride (SbF₃), antimony chloride (SbCl₃, SbCl₅), antimony bromide (SbBr₃) are used as the dopant.

This blend is heated to a temperature higher than the melting point of the raw material under a non-oxidizing gas atmosphere to thereby melt the blend. The non-oxidizing gas is, for example, argon gas or a mixture of argon gas and hydrogen (step S2). After melting, the blend is mixed while cooling to obtain an alloy ingot.

The resulting alloy ingot is roughly ground in the presence of a solvent (step S3), and mechanically ground in the presence of the solvent by a grinding method using a vibration mill or the like (step S4) to prepare an alloy powder having an average particle size of 1 to 20 μm, preferably 1 to 10 μm.

Here, when a p-type thermoelectric material is to be prepared, as the solvent, hexane, or a solvent represented by CₙH₂ₙ₊₁OH or CₙH₂ₙ₊₂CO (where n is 1, 2 or 3) can be used. When an n-type thermoelectric material is to be prepared, a solvent represented by CₙH₂ₙ₊₁OH or CₙH₂ₙ₊₂CO (where n is 1, 2 or 3) can be used.

The solvent represented by CₙH₂ₙ₊₁OH or CₙH₂ₙ₊₂CO (where n is 1, 2 or 3) includes methanol, ethanol, propanol, acetoaldehyde, acetone and methyl ethyl ketone.

Thereafter, classification is performed with a stainless sieve in such a manner that the powder is contacted with the air as little as possible and the particle size is of a predetermined particle size or less, while immersing the resulting ground powder in a solvent used for grinding (step S5). Thereafter, the classified ground powder is filtered (step S6) to remove a rough particle powder and a fine particle powder, and a particle size of a powder is adjusted.

Like this, by performing the treatments at steps S3 to S6 in the solvent, adsorption of oxygen onto an alloy powder can be suppressed, and formation of a solid solution by oxygen diffusion into a thermoelectric material obtained by firing can be prevented. As a result, since the carrier density in a thermoelectric material is increased and a specific resistance is decreased, it becomes possible to obtain a thermoelectric material having a further improved figure of merit Z.

Thereafter, the alloy powder, a particle size of which has been adjusted by filtering, is subjected to hot press in the presence of the solvent. It is desirable to perform hot press under the non-oxidizing gas atmosphere such as argon gas and a mixture gas of argon gas and hydrogen gas. In addition, hot press treatment is performed for 0.3 to 5 hours under the temperature pressure conditions proceeding sintering well and suppressing c plane orientation (step S7).

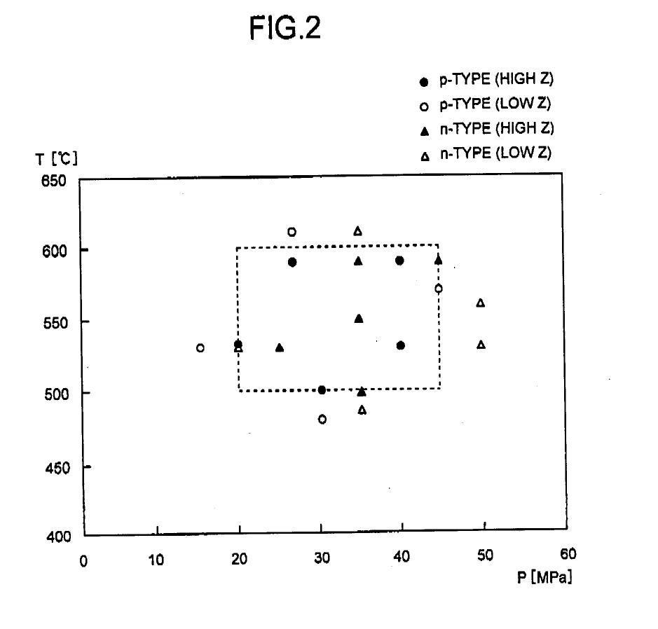

The temperature and pressure conditions proceeding sintering well and suppressing c plane orientation will be explained. FIG. 2 is a pressure-temperature view in which an abscissa axis is a pressure P (MPa) at hot press, and an ordinate axis is a temperature T [°C.] at hot press. In this FIG. 2, the conditions in a range surrounded by a broken line, that is, the hot press treatment conditions satisfying 20 MPa≦P≦45 MPa and 500° C.≦T≦600° C. are hot press treatment conditions proceeding sintering well and suppressing c plane orientation. More particularly, in the case of a p-type thermoelectric material, a pressure range is 20 MPa≦P≦40 MPa and a temperature range is 500° C.≦T≦600° C. On the other hand, in the case of an n-type thermoelectric material, a pressure range is 25 MPa≦P≦45 MPa and a temperature range is 500° C.≦T≦600° C.

In this case, when hot press treatment is performed at a lower pressure as compared with 20 MPa in the case of the p-type thermoelectric material and at a lower pressure as compared with 25 MPa in the case of an n-type thermoelectric material, c plane orientation is suppressed low. However, since sintering is insufficient, a density of a thermoelectric material becomes low, and a figure of merit is decreased. On the other hand, when hot press treatment is performed at a higher pressure as compared with 40 MPa in the case of a p-type thermoelectric material and at a higher pressure as compared with 45 MPa in the case of an n-type thermoelectric material, sintering is sufficiently promoted. However, since c plane orientation of a thermoelectric material becomes strong and the thermal conductivity is increased, the figure of merit is decreased.

When hot press treatment of a p-type or n-type thermoelectric material is performed at a lower temperature as compared with 500° C., c plane orientation is suppressed. However, since atomic diffusion is hardly caused and particle growth does not proceed, sintering becomes insufficient. On the other hand, when hot press treatment of a p-type or n-type thermoelectric material is performed at a higher temperature as compared with 600° C., since sintering proceeds too much and discontinuous particle growth is caused and, additionally, a material is melted and c plane orientation is heightened depending on a composition ratio, a figure of merit is decreased.

The reason why a figure of merit is increased by suppressing c plane orientation of a sufficiently sintered thermoelectric material is that the physical properties as a bulk material become isotropic by random directions of respective crystal particles.

Therefore, in order to obtain a p-type thermoelectric material having a high figure of merit, it is necessary to have a sintering degree of the thermoelectric material well proceeded and, at the same time, suppress c plane orientation. As the hot press treatment conditions, therefore, 20 MPa≦P≦40 MPa and 500° C.≦T≦600° C. are required in the case of a p-type thermoelectric material, 25 MPa≦P≦45 MPa and 500° C.≦T≦600° C. are required in the case of an n-type thermoelectric material.

Although treatment is performed in a solvent in the steps S3 to S7, in order that a ground powder of an alloy is contacted with oxygen in the air as little as possible, treatments of aforementioned steps S3 to S7 may be performed under the non-oxidizing gas atmosphere in place of the solvent. Also by treating under such non-oxidizing gas atmosphere, adsorption of oxygen onto an alloy powder can be suppressed, and formation of a solid solution by entrance of oxygen into a thermoelectric material obtained sintering can be prevented. As a result, it becomes possible to obtain a thermoelectric material having further improved figure of merit Z.

By the process explained above, the oxygen concentration is suppressed and sintering proceeds well, whereby, a thermoelectric material with suppressed c plane orientation can be obtained. And, such thermoelectric material has a further higher figure of merit Z as compared with the thermoelectric material prepared by the previous process.

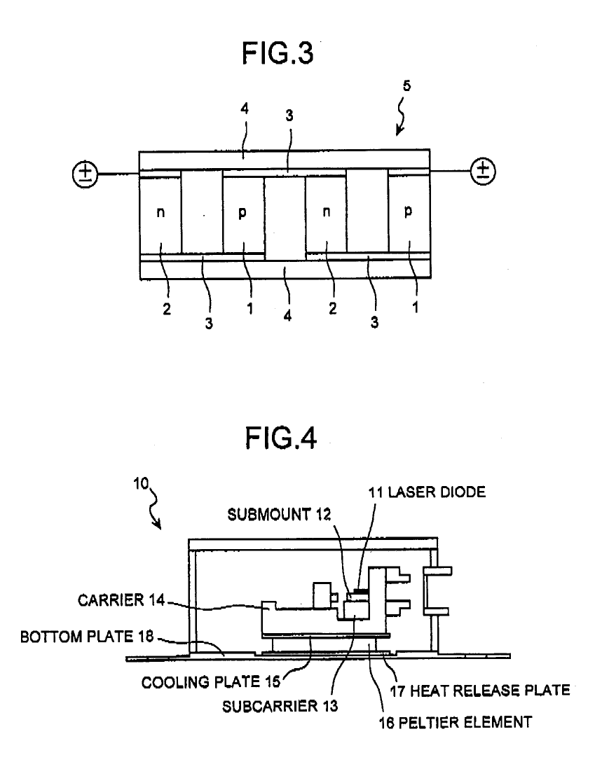

FIG. 3 is a schematic view that shows a structure of a Peltier element. As shown in this FIG. 3, a Peltier element 5 is prepared by connecting a p-type thermoelectric device 1 and an n-type thermoelectric device 2 prepared by the aforementioned steps alternately with an electrode 3, and holding a surface defined by an electrode 3 with insulating substrates 4.

FIG. 4 is a schematic view that shows one example of a structure of an optical module using the thus obtained Peltier element. In an optical module 10 shown in FIG. 4, a laser diode 11 is arranged on a material having great thermal conductivity for promoting heat release, for example, a submount 12 comprising diamond. The submount 12 is arranged on a subcarrier 13 made of a Cu—W alloy that also have the great thermal conductivity, and the subcarrier 13 is arranged on a carrier 14 made of a Cu—W alloy. And, a Peltier element 16 for cooling them is mounted between a carrier 14 and a bottom plate 18 made of a Cu—W alloy via a cooling plate 15 comprising an electrically insulating material such as Al₂O₃ and a heat release plate 17 such as Al₂O₃.

In this optical module 10, by using the thermoelectric material having a high figure of merit prepared by the present process as a Peltier element 16, a temperature of a high output laser diode 11 can be effectively controlled.

Concrete examples and comparative examples of the present invention will be explained specifically below.

### FIRST TO THIRD EXAMPLES AND FIRST AND SECOND COMPARATIVE EXAMPLES

As a p-type thermoelectric material, (Sb_{0.8}Bi_{0.2)}₂Te₃ was selected, Te was added as a dopant as an atomic ratio shown in the following Table 1, to the p-type thermoelectric material to change the carrier density, and the relationship between the density of Te as a dopant with a figure of merit and an orientation degree was obtained.

TABLE 1

| | Te added | (001) | | | Power | | |
|---|---|---|---|---|---|---|---|
| | amount | Plane | Specific | Seedbeck | factor | Thermal | FIGURE of |
| | (atomic | orientation | resistance | coefficient | [×10⁻³mW | conductivity | merit |
| | ratio) | degree | [mΩ · cm] | [μV/K] | /cm · K²] | [mW/cm · K] | [×10⁻³/K] |
| Example 1 | 0 | 0.083 | 1.062 | 215.8 | 43.9 | 12.2 | 3.59 |
| Example 2 | 0.08 | 0.130 | 0.913 | 202.7 | 45.0 | 12.7 | 3.54 |
| Example 3 | 0.2 | 0.171 | 0.834 | 195.3 | 45.7 | 13.0 | 3.52 |
| Comparative | 0.3 | 0.206 | 0.840 | 192.6 | 44.2 | 13.3 | 3.52 |
| Example 1 | | | | | | | |
| Comparative | 0.4 | 0.278 | 0.829 | 194.1 | 45.4 | 13.6 | 3.34 |
| Example 2 | | | | | | | |

The thermal conductivity was measured in an electrifying direction.

Flakes of Sb, Bi and Te (all high purity reagents having purity of 4 N (99.99%)) were weighed so that antimony telluride (Sb₂Te₃) and bismuth telluride (Bi₂Te₃) became an alloy ratio of 80:20 (molar ratio) and, further, such a composition was obtained that Te of an atomic ratio of 0.08 was added in the second example, Te of an atomic ration of 0.2 was added in the third example, Te of an atomic ration of 0.3 was added in the first comparative example, and Te of an atomic ratio of 0.4 was added in the second comparative example. These weighed materials were melted and mixed in a graphite crucible at 690° C. for 1 hour in the mixed gas atmosphere of argon gas (99%) and hydrogen gas (1%). Thereafter, the melt was spontaneously cooled to around room temperature to prepare an alloy ingot having a desired composition.

Using n-hexane as a solvent, this alloy ingot was roughly ground, ground with a vibration mill for 10 hours, and a ground powder was adjusted with a sieve. An average particle size of ground powder obtained by grinding for 10 hours was about 6 μm. Thereafter, a ground powder immersed in n-hexane was packed in a graphite dice, and subjected to hot press treatment at 530° C. for 1 hour under a pressure of 27 MPa in the mixed gas atmosphere of argon gas (97%) and hydrogen gas (3%).

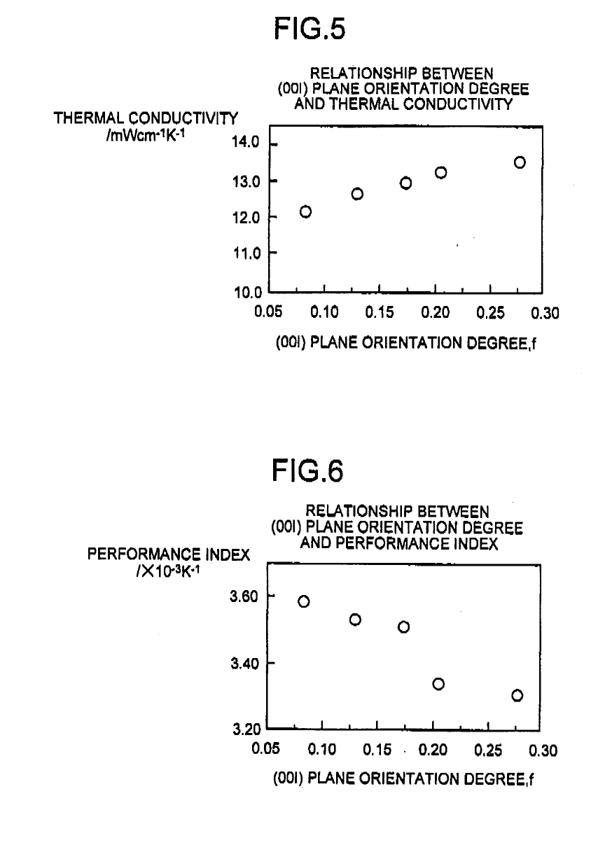

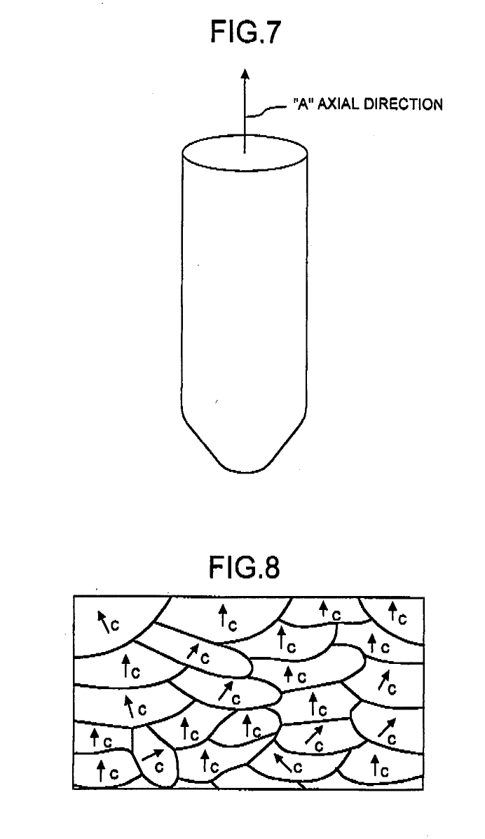

A sintered sample of the thus obtained p-type thermoelectric material was processed into an arbitrary shape, and the specific resistance, Seebeck coefficient, power factor, and the thermal conductivity were measured, and a c plane orientation degree and a figure of merit were calculated. The results are shown in Table 1. FIG. 5 is a graph that shows the relationship between the c plane orientation degree f and the thermal conductivity κ from Table 1, and FIG. 6 is a graph that shows the relationship between the c plane orientation degree f and the figure of merit Z from Table 1.

The c plane orientation degree was obtained by using an equation for calculating orientation degree proposed by Lotgerling after a plane perpendicular to a press direction of the resulting sample was measured by an X-ray diffraction method. 2θ=5° to 80° was measured by using RU-200 type manufactured by Rigakudenki as an X-ray diffraction apparatus and using CuKα-ray. A tube voltage at measurement was 40 kV and a tube current was 150 mA.

A method of calculating the c plane orientation degree f by the Lotgerling method will be explained below. First, a sample is measured at a range of 2θ=5° by an X-ray diffraction method. And, a ratio P of a sum of the diffraction intensity of diffraction peaks from all of the c planes ((00l) plane=(003), (006), (0015), (0018) and (0021) planes) in the detected phase of interest relative to a sum of the diffraction intensity of diffraction peaks from all (hkl) planes in the detected phase of interest is obtained by the following equation:

P=Σl(00l)/Σl(hkl)

A ratio Po of a sum of the diffraction intensities of the c plane relative to a sum of the diffraction intensities of all diffraction peaks at 2θ=5 to 80° regarding a standard sample registered in the literature “JCPDS Powder Diffraction File” is obtained.

From these P and Po, the c plane orientation degree f of phase of interest is obtained by the following equation:

f=(P−Po)/(1−Po) (2)

If the f value obtained by this equation (2) is near 1, it shows that a sample has a higher c plane orientation, and the value near 0 shows that directions of respective crystal particles in a sample are random. In the present invention, “low c plane orientation” refers to a sample having the c plane orientation degree f of 0.2 or smaller, more preferably a sample having the c plane orientation degree f of 0.15 or smaller.

In calculation of the c plane orientation degree f, as a standard sample of a solid solution Bi₂Te₃—Sb₂Te₃ which is a composition excessive in Sb₂Te₃, JCPDS Powder Diffraction File No. 15-0874 was used.

As seen from Table 1, as an amount of Te as a dopant to be added grows larger, the c plane orientation degree f is increased. The reason is considered that, by a pressure at hot press, a sufficient amount of a liquid phase for orienting particles in one direction is produced by excessive Te. In addition, when the c plane orientation degree f is increased, the thermal conductivity κ is also increased as seen from FIG. 5. From the equation (1), since the thermal conductivity κ and the figure of merit Z are in a inversely proportional to each other, when the c plane orientation degree f is increased, the figure of merit Z is decreased as shown in FIG. 6. That is, it can be seen that, in order to increase the figure of merit Z, it is enough to decrease the c plane orientation degree f.

As described above, since it is considered that the c plane orientation degree f is related to an amount of a liquid phase, in order to control an amount of a liquid phase below a prescribed amount, it is necessary to render an amount of a dopant to be added below a prescribed amount. From Table 1, x=around 0.2 where the figure of merit Z is as high as 3.4×10⁻³K⁻¹ and the c plane orientation degree f is 0.2 or smaller is considered to be a limit value for an amount of a dopant to be added. Therefore, an amount of Te as a dopant to be added for obtaining a p-type thermoelectric material having a composition of (Sb_{0.8}Bi_{0.2})₂Te₃ and having the high figure of merit is 0.2 or smaller as an atomic ratio.

### FOURTH TO NINTH EXAMPLES AND THIRD TO SIXTH COMPARATIVE EXAMPLES

As a p-type thermoelectric material, (Sb_{o.8}Bi_{0.2)}₂Te₃ was selected, Te was added as a dopant as an atomic ratio of 0.08, to the p-type thermoelectric material, and the relationship between the figure of merit and the c plane orientation degree was obtained when a temperature and a pressure at hot press was changed.

Flakes of Sb, Bi and Te (all high purity reagents having purity of 4 N (99.99%)) were weighed so that antimony telluride (Sb₂Te₃) and bismuth telluride (Bi₂Te₃) became an alloy ratio of 80:20 (molar ratio) and an atomic ratio of Te as a dopant became 0.08. These weighed materials were melted and mixed in a graphite crucible at 690° C. for 1 hour in the mixed gas atmosphere of argon gas (99%) and hydrogen gas (1%). Thereafter, the melt was spontaneously cooled to around room temperature to prepare an alloy ingot having a desired composition.

Using n-hexane as a solvent, this alloy ingot was roughly ground, ground with a vibration mill for 10 hours, and a ground powder was adjusted with a sieve. An average particle size of ground powder obtained by grinding for 10 hours was about 6 μm. Thereafter, a ground powder immersed in n-hexane was packed in a graphite dice, and subjected to hot press treatment at a temperature and a pressure shown in the following Table 2 for 1 hour in the mixed gas atmosphere of argon gas (97%) and hydrogen gas (3%).

A sintered sample of the thus obtained p-type thermoelectric material was processed into an arbitrary shape, and a Seebeck coefficient, a specific resistance, an power factor and a thermal conductivity were measured, and a c plane orientation degree and a figure of merit were calculated. The results are shown in Table 2. In addition, the c plane orientation degree was obtained by using the equation (2) from measurement of planes perpendicular to a press direction of the resulting sample by an X-ray diffraction method.

TABLE 2

| | | | | | Power | | | (001) |
|---|---|---|---|---|---|---|---|---|
| | HP | HP | Seebeck | Specific | factor | Thermal | FIGURE of | Plane |
| | Pressure | Temperature | coefficient | resistance | [×10⁻³mW | conductivity | merit | orientation |
| | [Mpa] | [° C.] | [μV/K] | [mΩ · cm] | /cm · K²] | [mW/cm · K] | [×10⁻³/K] | degree |
| Example 4 | 20 | 530 | 209.5 | 1.120 | 39.2 | 11.5 | 3.41 | 0.087 |
| Example 5 | 27 | 590 | 196.1 | 0.946 | 40.7 | 11.9 | 3.42 | 0.142 |
| Example 6 | 27 | 590 | 202.0 | 0.893 | 45.7 | 13.1 | 3.49 | 0.123 |
| Example 7 | 30 | 500 | 221.3 | 1.320 | 37.1 | 10.9 | 3.40 | 0.119 |
| Example 8 | 40 | 590 | 203.2 | 0.852 | 48.5 | 14.1 | 3.44 | 0.149 |
| Example 9 | 40 | 530 | 206.7 | 1.001 | 42.7 | 12.4 | 3.44 | 0.182 |
| Comparative | 15 | 530 | 212.1 | 1.270 | 35.4 | 11.2 | 3.16 | 0.117 |
| Example 3 | | | | | | | | |
| Comparative | 27 | 610 | 214.5 | 1.235 | 37.3 | 14.1 | 2.64 | 0.263 |
| Example 4 | | | | | | | | |
| Comparative | 30 | 480 | 210.7 | 1.210 | 36.7 | 11.6 | 3.16 | 0.095 |
| Example 5 | | | | | | | | |
| Comparative | 45 | 570 | 203.2 | 0.922 | 44.8 | 13.7 | 3.27 | 0.237 |
| Example 6 | | | | | | | | |

The thermal conductivity was measured in an electrifying direction.

As shown in Table 2, there is a tendency that specific resistances of the fourth to ninth examples are lower as compared with those of the third to sixth comparative examples having approximately same Seebeck coefficients. Therefore, from equation (1), the figure of merits Z of the thermoelectric materials of the fourth to ninth examples are higher than those of the thermoelectric materials of the third to sixth comparative examples.

From Table 2, a tendency can be seen that the thermoelectric materials having a higher figure of merit Z have the low c plane orientation degree (=(00l) plane orientation degree) f of 0.2 or smaller. Further, among them, all except for the ninth example have the low c plane orientation degree of 0.15 or smaller. However, the third and fifth comparative examples have the low c plane orientation degree f, but have lower figure of merits Z as compared with those of the fourth to ninth examples. The reason is considered that since a pressure is low in the case of the third comparative example and a temperature is low in the fifth comparative example, sintering did not proceed sufficiently in both cases. Therefore, in order to obtain a thermoelectric material having a high figure of merit Z, it is necessary to suppress the c plane orientation degree and, at the same time, increase a sintering degree of the thermoelectric material.

FIG. 2 is a view that shows a combination of a temperature and a pressure of the fourth to ninth examples and the third to sixth comparative examples shown in Table 2, and the better or the worse property of a figure of merit Z at that time. Solid circles show the fourth to ninth examples having a figure of merit of 4×10⁻³K⁻¹ or larger, and hollow circles shows the third to sixth comparative examples having a lower figure of merit as compared with the examples, it can be seen from FIG. 2 that, the temperature and pressure conditions at hot press for manufacturing a p-type thermoelectric material having a high figure of merit Z are 20 MPa≦P≦400 MPa and 500° C.≦T≦600° C.

Therefore, when the hot pressing is performed under the temperature and pressure conditions of 20 MPa≦P≦400 MPa and 500° C.≦T≦600° C., a p-type thermoelectric material having a high figure of merit Z is obtained and, the p-type thermoelectric material upon this becomes to have the low c plane orientation degree where a sintering degree has proceeded sufficiently.

TENTH TO FOURTEENTH EXAMPLES AND SEVENTH TO ELEVENTH COMPARATIVE EXAMPLES

As an n-type thermoelectric material, Bi₂(Te_{0.95}Se_{0.05})₃ was selected, 4 wt % tellurium iodide (TeI₄) was added as a dopant to the n-type thermoelectric material, and the relationship between the figure of merit and the c plane orientation degree was obtained when a temperature and a pressure at hot press were changed.

Flakes of Se, Bi and Te (all high purity reagents having purity of 4 N (99.99%)) were weighed, respectively, so that bismuth telluride (Bi₂Te₃) and bismuth selenide (Bi₂Se₃) became an alloy ratio of 95:5 (molar ratio) and a weight ratio of TeI₄ as a dopant became 4%. These weighed materials were melted and mixed in a graphite crucible at 690° C. for 2 hours in the mixed gas atmosphere of argon gas (99%) and hydrogen gas (1%). Thereafter, the melt was spontaneously cooled to around room temperature to prepare an alloy ingot having a desired composition.

Using methanol as a solvent, this alloy ingot was roughly ground, ground with a vibration mill for 10 hours, and the ground powder was adjusted with a sieve. An average particle size of ground powder obtained by grinding for 10 hours was about 6 μm. Thereafter, the ground powder immersed in methanol was packed in a graphite dice, and subjected to hot press treatment at a temperature and a pressure shown in the following Table 3 for 1 hour in the mixed gas atmosphere of argon gas (97%) and hydrogen gas (3%).

A sintered sample of the thus obtained n-type thermoelectric material was processed into an arbitrary shape, and Seebeck coefficient, specific resistance, power factor, and thermal conductivity of the material were measured. Moreover, c plane orientation degree and figure of merit of the material were calculated. The results are shown in Table 3. In addition, the c plane orientation degree was obtained by using the equation (2) from measurement of planes perpendicular to a press direction of the resulting sample by an X-ray diffraction method. Upon this, as a standard sample of a solid solution Bi₂Te₃—Bi₂Se₃ which is a composition excessive in Bi₂Te₃, JCPDS Powder Diffraction File No. 15-0863 was used.

TABLE 3

| | | | | | Power | | | (001) |
|---|---|---|---|---|---|---|---|---|
| | HP | HP | Seebeck | Specific | factor | Thermal | FIGURE of | Plane |
| | Pressure | Temperature | coefficient | resistance | [×10⁻³mW | conductivity | merit | orientation |
| | [Mpa] | [° C.] | [μV/K] | [mΩ · cm] | /cm · K²] | [mW/cm · K] | [×10⁻⁴/K] | degree |
| Example 10 | 25 | 530 | −210.0 | 1.280 | 34.5 | 11.7 | 2.94 | 0.092 |
| Example 11 | 35 | 500 | −205.0 | 1.150 | 36.5 | 12.4 | 2.95 | 0.102 |
| Example 12 | 35 | 550 | −210.1 | 1.170 | 37.7 | 12.0 | 3.14 | 0.091 |
| Example 13 | 35 | 590 | −241.0 | 1.610 | 36.1 | 11.2 | 3.22 | 0.100 |
| Example 14 | 45 | 590 | −221.0 | 1.340 | 36.4 | 12.4 | 2.94 | 0.150 |
| Comparative | 20 | 530 | −213.2 | 1.410 | 32.2 | 11.7 | 2.76 | 0.076 |
| Example 7 | | | | | | | | |
| Comparative | 35 | 490 | −228.7 | 1.546 | 33.8 | 12.8 | 2.64 | 0.082 |
| Example 8 | | | | | | | | |
| Comparative | 35 | 610 | −218.0 | 1.350 | 35.2 | 14.0 | 2.51 | 0.286 |
| Example 9 | | | | | | | | |
| Comparative | 50 | 530 | −213.6 | 1.223 | 37.3 | 14.3 | 2.61 | 0.189 |
| Example 10 | | | | | | | | |
| Comparative | 50 | 560 | −219.6 | 1.250 | 38.6 | 13.4 | 2.88 | 0.253 |
| Example 11 | | | | | | | | |

The thermal conductivity was measured in an electrifying direction.

As shown in Table 3, there is a tendency that specific resistances of the tenth to fourteenth examples are lower than those of the seventh to eleventh comparative examples having approximately same the Seebeck coefficients. In addition, there is a tendency that the thermal conductivities of the tenth to fourteenth examples are lower than those of the seventh to eleventh comparative examples having approximately same power factors. Therefore, from the equation (1), figure of merits Z of the thermoelectric materials of the tenth to fourteenth examples have increased than those of the thermoelectric materials of the seventh to eleventh comparative examples.

From Table 3, a tendency can be seen that thermoelectric materials having a higher figure of merit Z have the low c plane orientation degree (=(001) plane orientation degree) f of 0.15 or smaller. However, the seventh and eighth comparative examples have lower c plane orientation degree, but have lower values of figure of merits Z as compared with those of the tenth and fourteenth examples. The reason is that since a temperature is low in the case of the seventh comparative example and a pressure is low in the case of the eighth comparative example, sintering has not proceeded sufficiently in both cases. Therefore, in order to obtain a thermoelectric material having a high figure of merit Z, it is necessary to suppress the c plane orientation degree and increase a sintering degree of the thermoelectric material.

FIG. 2 is a graph that shows a combination of a pressure and a temperature in the tenth to fourteenth examples and the seventh to eleventh comparative examples shown in Table 3, and the better or worse property of a figure of merit Z at that time. Solid triangles show the tenth to fourteenth examples having a high figure of merit of 2.9×10⁻³K⁻¹ or greater and hollow triangles show the seventh to eleventh comparative examples having lower figure of merits Z as compared with those of the tenth to fourteenth examples. From this FIG. 2, the temperature and pressure conditions at hot press for manufacturing an n-type thermoelectric material having a high figure of merit Z are 25 MPa≦P≦45 MPa and 500° ≦T≦600° C.

Therefore, when hot press treatment is performed under the temperature and pressure conditions of 25 MPa≦P≦45 MPa and 500° C.≦T≦600° C., an n-type thermoelectric material having a high figure of merit Z is obtained and, the n-type thermoelectric material upon this becomes to have the low c plane orientation degree where a sintering degree has proceeded sufficiently.

As explained above, the thermoelectric material obtained by the process of the present invention comes to have a better figure of merit by suppressing the c plane orientation and having sintering proceeded sufficiently. Therefore, the thermoelectric material having a high figure of merit obtained by the process of the present invention can be applied to the fields requiring further precise temperature control, by utilizing the Peltier effect as a thermoelectric device.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A process for manufacturing a thermoelectric material, comprising:
mixing and melting at least two members selected from bismuth, tellurium, selenium, antimony, and sulfur to obtain an alloy ingot;
grinding the alloy ingot to obtain powder of the alloy ingot; and
hot pressing the powder,
wherein the hot pressing is performed under the conditions of a temperature of 500° C. or higher and 600° C. or lower and a pressure of 20 MPa or higher and 45 MPa or lower.

2. The process according to claim 1, wherein the hot pressing is performed under a non-oxidizing gas atmosphere.

3. The process according to claim 1, wherein an average particle size of the powder is 1 to 20 μm.

4. The process according to claim 1, wherein the thermoelectric material is a p-type thermoelectric material,
any one of selenium and tellurium is used as a dopant at the mixing and melting, and
an amount of the dopant to be added is an atomic ratio of 0.2 or lower.

5. The process according to claim 4, wherein the grinding and the hot pressing are performed in the presence of any one of hexane and a solvent represented by CₙH₂ₙ₊₁OH or CₙH₂ₙ₊₂CO (where n is 1, 2 or 3).

6. The process according to claim 1, wherein the thermoelectric material is an n-type thermoelectric material, and
at least one member selected from bismuth fluoride (BiF₃), bismuth chloride (BiCl₃), bismuth bromide (BiBr₃), bismuth iodide (Bil₃), tellurium chloride (TeCl₄), tellurium iodide (TeI₂, TeI₄), tellurium bromide (TeBr₄), selenium chloride (SbCl₄), selenium bromide (SeBr₄), selenium iodide (SeI₄), antimony fluoride (SbF₃), antimony chloride (SbCl₃, SbCl₅), and antimony bromide (SbBr₃) is used as a dopant at the mixing and melting.

7. The process according to claim 6, wherein the grinding and the hot pressing are performed in the presence of a solvent represented by CₙH₂₊₁OH or CₙH₂ₙ₊₂CO (where n is 1, 2 or 3).

8. A thermoelectric material prepared by the process according to claim 1, wherein
an orientation degree of a (00l) plane of the thermoelectric material obtained by an X-ray diffraction method in a plane perpendicular to a hot press direction of the thermoelectric material is 0.2 or smaller.

9. A Peltier element comprising:
an arrangement in which a plurality of the p-type thermoelectric devices prepared by the process according to claim 4 and the n-type thermoelectric devices prepared by the process according to claim 6 are arranged alternately;
electrodes that electrically connect adjoining p-type thermoelectric device and n-type thermoelectric device; and
electrically insulating substrates that hold the electrodes.
